(19) United States
(12) Patent Application Publication
(10) Pub. No.: US 2023/0042091 A1
(43) Pub. Date: Feb. 9, 2023

(54) GRAPHICAL CONFIGURATION EDITOR FOR HIGHWAY-RAIL GRADE CROSSINGS AND ASSOCIATED METHOD

(71) Applicant: Siemens Mobility, Inc., New York, NY (US)

(72) Inventors: Richard Bamfield, Ruby Bay (NZ); Gustavo Guillen, Fountain Valley, CA (US)

(21) Appl. No.: 17/817,031

(22) Filed: Aug. 3, 2022

Related U.S. Application Data
(60) Provisional application No. 63/203,909, filed on Aug. 4, 2021.

(51) Int. Cl. G06F 30/13; G06F 30/12

(52) U.S. Cl. CPC G06F 30/13; G06F 30/12

(57) ABSTRACT

A graphical configuration editor for highway-rail grade crossings includes a storage device comprising an application, and a processor configured to execute instructions of the application to generate, on a display, identifications of a plurality of objects for controlling a grade crossing, receive user input comprising a selection of objects out of the plurality of objects, generate, on the display, a visual representation of a track plan using the selected objects, and store the track plan in the storage device. Further, associated method(s) and a grade crossing controller are described.

### BACKGROUND

### 1. Field

Aspects of the present disclosure generally relate to highway-rail grade crossings, specifically a graphical configuration editor and a method for creating a representation of a track plan, in connection with grade crossing control systems including for example a grade crossing predictor system.

### 2. Description of the Related Art

Railroad signal control equipment includes for example a constant warning time device, also referred to as a grade crossing predictor (GCP) in the U.S. or a level crossing predictor in the U.K., which is an electronic device that is connected to the rails of a railroad track and is configured to detect the presence of an approaching train and determine its speed and distance from a crossing, i.e., a location at which the tracks cross a road, sidewalk or other surface used by moving objects. The constant warning time device will use this information to generate a constant warning time signal for controlling a crossing warning device. A crossing warning device is a device that warns of the approach of a train at a crossing, examples of which include crossing gate arms (e.g., the familiar black and white striped wooden arms often found at highway grade crossings to warn motorists of an approaching train), crossing lights (such as the red flashing lights often found at highway grade crossings in conjunction with the crossing gate arms discussed above), and/or crossing bells or other audio alarm devices. Constant warning time devices are typically configured to activate the crossing warning device(s) at a fixed time, also referred to as warning time (WT), which can be for example 30 seconds, prior to the approaching train arriving at a crossing.

Grade crossings can be configured by specifying a set of values for configuration parameters for the grade crossing equipment or by writing specific application logic for each crossing. However, a problem with these approaches is that it is not easy to visualize the relationship between the setting of the configuration parameters and the track layout. This increases the likelihood of errors in the design. It also causes issues for maintenance personnel as there is no simple way to relate the crossing equipment to the actual field devices without looking at the plans for the specific crossing.

An option is to simplify crossing designs by allowing a user to select a template for the crossing to be designed from a predefined set. This solution is partially successful, however since the templates do not represent the actual layout of the crossing in terms of where the predictors are placed, this method may lead to some confusion amongst users.

### SUMMARY

Aspects of the present disclosure generally relate to highway-rail grade crossings, specifically a graphical configuration editor and a method for creating a representation of a track plan, in connection with grade crossing control systems including for example a grade crossing predictor system.

A first aspect of the present disclosure provides a graphical configuration editor for highway-rail grade crossings, the graphical configuration editor comprising a storage device comprising an application, and a processor configured to execute instructions of the application to generate, on a display, identifications of a plurality of objects for controlling a grade crossing, receive user input comprising a selection of objects out of the plurality of objects, generate, on the display, a visual representation of a track plan using the selected objects, and store the track plan in the storage device.

A second aspect of the present disclosure provides a method for creating a visual representation of a track plan, the method comprising generating, on a display, identifications of a plurality of objects for controlling a grade crossing, receiving user input comprising a selection of objects out of the plurality of objects, generating, on the display, a visual representation of a track plan using the selected objects, and storing the track plan in a storage device.

Further aspects of the present disclosure provide a non-transitory computer readable medium storing executable instructions that when executed by a computer perform a method for creating a visual representation of a track plan, and a grade crossing controller comprising a storage device and a display, wherein the grade crossing controller stores a graphical representation of a track plan and is configured to display the graphical representation of the track plan on demand.

### BRIEF DESCRIPTION OF THE DRAWINGS

FIG. 1 illustrates a schematic of a highway-rail grade crossing including a warning system in accordance with an embodiment disclosed herein.

FIG. 2 illustrates an example constant warning time device in accordance with an embodiment disclosed herein.

FIG. 3 illustrates a schematic of a graphical configuration editor in accordance with an exemplary embodiment of the present disclosure.

FIG. 4 illustrates a schematic of a graphical representation of track plan created with a graphical configuration editor in accordance with an exemplary embodiment of the present disclosure.

FIG. 5 illustrates a flow chart of a method for creating a track plan for a highway-rail grade crossing warning system in accordance with embodiments of the present disclosure.

### DETAILED DESCRIPTION

To facilitate an understanding of embodiments, principles, and features of the present disclosure, they are explained hereinafter with reference to implementation in illustrative embodiments. In particular, they are described in the context of devices and methods for creating a representation of a track plan utilizing a graphical configuration editor.

The components and materials described hereinafter as making up the various embodiments are intended to be illustrative and not restrictive. Many suitable components and materials that would perform the same or a similar function as the materials described herein are intended to be embraced within the scope of embodiments of the present disclosure.

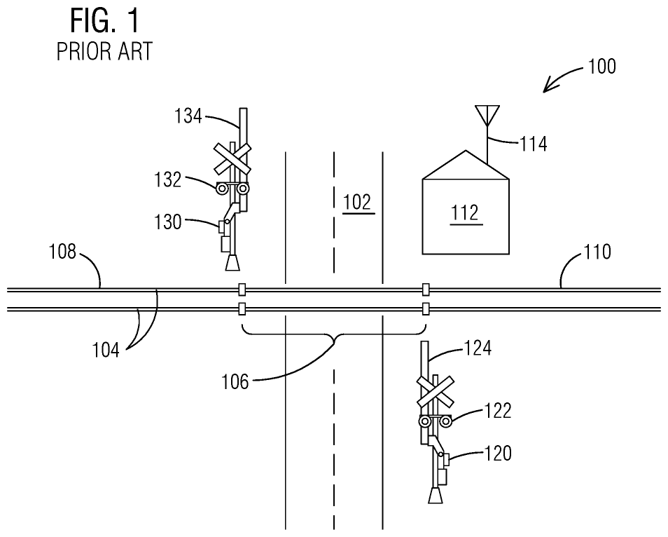

FIG. 1 illustrates a schematic of a highway-rail grade crossing 100 including a warning system in accordance with an embodiment disclosed herein.

Highway-rail grade crossing 100 is located at road 102 and at one or more railroad tracks 104. A Grade Crossing Predictor (GCP) system is enclosed within a generally weatherproof housing or bungalow 112, and in general proximity to at least one of the railroad tracks 104. The GCP system will also be hereinafter referred to as a controller or an electronic controller. For example, housing 112 is equipped with an antenna 114 to permit reception of signals and to transmit signals, such as between controller and a railroad operations center (not shown).

In a conventional manner, at least that portion of railroad track 104 that intersects with the road 102 is included in an island circuit 106 that is monitored by the GCP system. Those portions of track 104 that lie to the right and to the left of the island circuit 106 are included in an approach circuit, identified by reference numerals 108 and 110. Approach circuits 108, 110 are also monitored by the GCP system.

Traffic warning devices 120, 130 are typically placed on both sides of the track 104 and adjacent to road 102. These traffic warning devices 120, 130 are equipped with flashing lamps 122, 132, may be provided with gates 124, 134 that may be lowered, and audible devices, such as a bell or the like. When a train is detected in the approach circuits 108, 110, and/or in the island circuit 106, the GCP system activates the flashing lights 122, 132 and the audible devices and causes the gates 124, 134 of traffic warning devices 120, 130 to be lowered. The GCP system or controller is an integrated system that includes all the control, train detection, and monitoring of grade crossing warning systems, such as for the crossing 100 of FIG. 1.

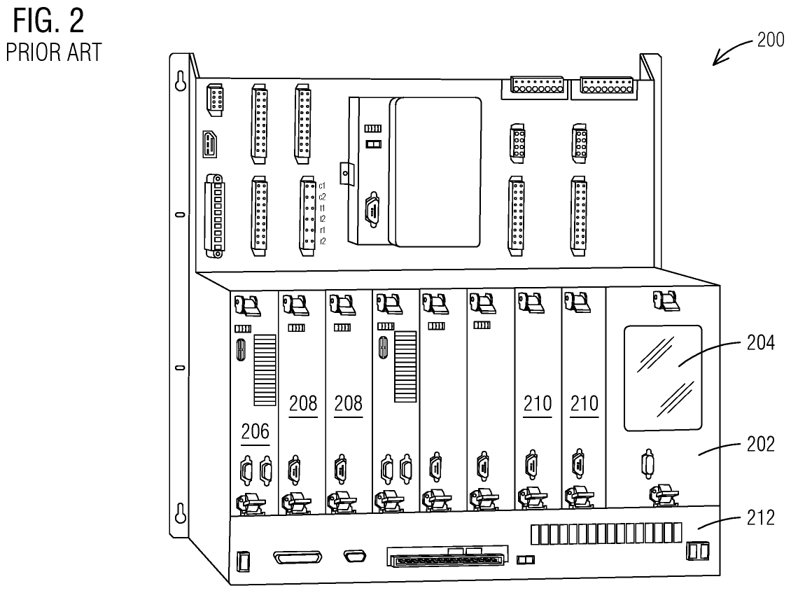

FIG. 2 illustrates an example constant warning time device (GCP system) 200 in accordance with an embodiment disclosed herein.

As noted, the GCP system 200 is typically enclosed within a generally weatherproof bungalow or housing 112 and usually in general proximity to at least one of the railroad tracks 104 (see FIG. 1). The GCP system 100 includes a plurality of modules. One of these modules is for example a display module 202 with a display 204. The display 204 provides a user interface, for example for initial setup, calibration and troubleshooting of the GCP system 200.

Other modules may include a central processing unit (CPU) 206, track modules 208 for monitoring each track, crossing control modules 210 for controlling traffic warning gates, and a recorder module 212 including one or more memory units for recording events and conditions at the railroad track system. Each of the modules may have external connectors, test points and lighted indicators.

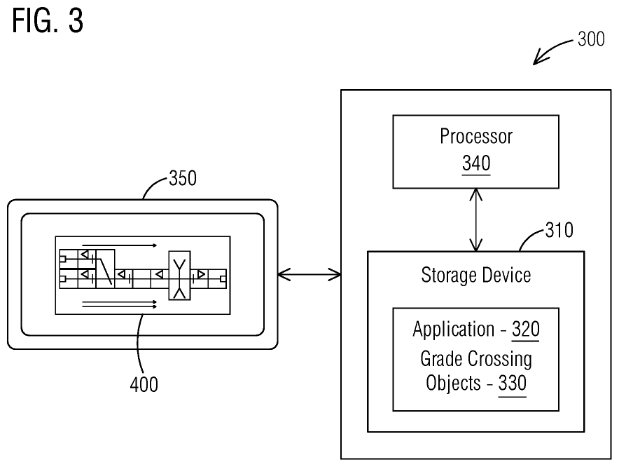

FIG. 3 illustrates a schematic of a graphical configuration editor 300 in accordance with an exemplary embodiment of the present disclosure.

The graphical configuration editor 300 comprises a storage device 310 comprising an application 320 with instructions for creating a representation of a track plan, such as exemplary track plan 400 shown on display 350. The application 320 utilizes objects 330 for controlling a grade crossing, wherein the objects 330 are stored in the storage device 310. The objects 330 are software objects and represent physical devices and systems in connection with a grade crossing.

A processor or computer 340 is configured to execute the instructions of the application 320, using the multiple objects 330. The objects 330 include for example representations of track lines, termination shunts, track circuits, transmitters etc. At least some of the objects 330 include default programming parameters for a controller of a grade crossing, for example a GCP controller 200 as illustrated in FIG. 2.

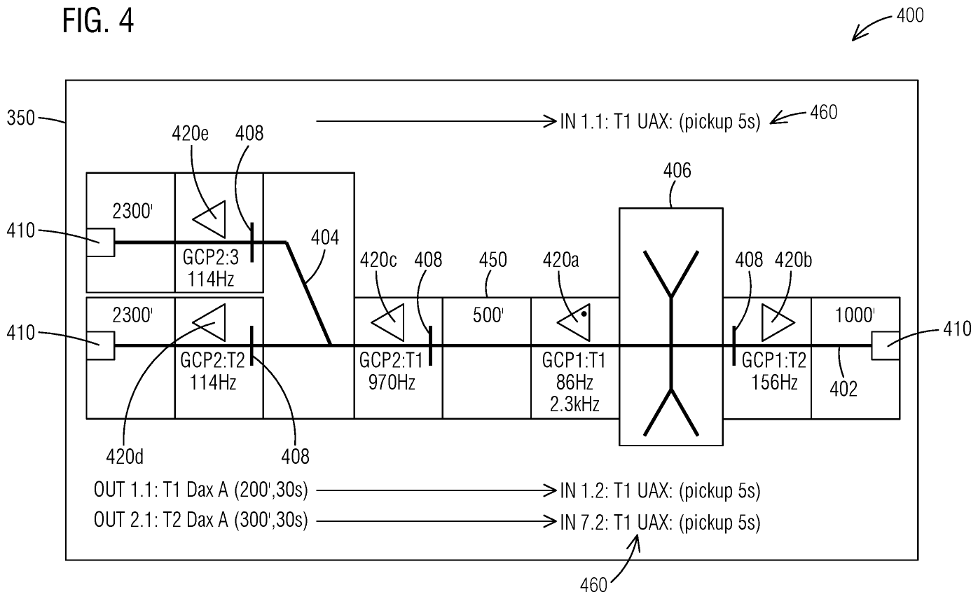

The graphical configuration editor 300 allows a user to draw a simple representation of a track plan, such as for example track plan 400, see also FIG. 4. For example, a designer or user, in an office setting, uses a computer and utilizing the graphical configuration editor 300, to draw a track layout, such as track plan 400, and to set a GCP configuration for a GCP system, such as GCP system 200 as shown in FIG. 2. One or more GCP systems can be interconnected. The graphical configuration editor 300 can be an application locally stored on a PC or can be a web-based application. The track plan 400 can be stored locally on the PC, in an external storage device, such as a USB stick or disk, or can be stored remotely, for example in a cloud storage. Thus, the processor 340 is configured to generate, on the display 350, identifications of the plurality of objects 330 for controlling a grade crossing. In an example, the identifications of the objects 330 include visual representations, such as symbols, configured for example as tiles that are selectable by the user. The processor or computer 340 is further configured to receive user input comprising a selection of objects 330 out of the plurality of objects 330, for example via drag-and-drop functionality, and to generate, on the display 350, a visual representation of the track plan 400, using the selected one or more object(s) 330 and store the track plan 400. The track plan 400 may be stored on the storage device 310 of the editor 300, and/or may be stored externally, for example on a separate storage device selected by the user or creator of the track plan.

The objects 330 comprises grade crossing device(s) of the grade crossing and/or remote devices for controlling the grade crossing. The objects 330 include for example railroad tracks, termination shunts, crossing, track modules etc. Remote devices include for example devices that are installed in the field and not being configured as part of the respective design/track plan but can be added by the user (designer) to give a more complete visual picture of the context of the crossing, e. g. track plan, being designed.

FIG. 4 illustrates a schematic of a graphical representation of track plan 400 created with a graphical configuration editor, such as editor 300, in accordance with an exemplary embodiment of the present disclosure.

As noted, the graphical configuration editor 300, as illustrated in FIG. 3, allows a user to draw a simple representation of a track plan, such as track plan 400, displayed at display or computer screen 350. The track plan 400 includes crossing device(s) at an actual crossing to be configured. For example, the graphical configuration editor 300 is a PC based application that the user or designer may run in an office. An output is the track plan 400, stored in a file, that can then be uploaded in a GCP system, such as GCP system 200, see FIG. 2. The track plan 400, when loaded in the GCP system, is used to configure, or program the GCP system, because the objects 330 in the track plan 400 include default programming parameters for a controller of a grade crossing, such as GCP system 200.

The track plan 400 includes multiple different objects or elements, that are selectable from the plurality of objects 330 included in the editor 300. The objects 330 and track plan 400 include visual representations and symbols. In the example of FIG. 4, the representations and symbols are implemented in tiles 450, that can be selected by the user/creator, for example via drag-and-drop functionality. The tiles 450 can be predefined tiles including one or more objects/symbols. Other equivalent method(s) may be implemented that capture the information of the track layout and placement of the elements for controlling the highway crossing. It should be noted that the implementation of tiles 450 is an example only, and the physical items can be represented in many different ways, such as icons.

The objects for controlling the grade crossing, available via the tiles 450, include tracks 402 (horizontal lines) and switches 404 (junction, converging or diverging tracks) that represent the railroad tracks (one track represents the two physical rails). Symbol/tile 406 including a vertical line with inverted arrows on either end represents the road, i. e. the crossing of road and rail track. Symbols 408 (small vertical line) on the track represents an insulated joint in the railroad tracks. Symbols 410 represent termination shunts on the railroad tracks. Together with the symbol 410 for a termination shunt, an approach length for the respective approach circuit is provided, for example 1000 ft or 2300 ft. Such a length or distance may be manually inserted by the user, or a variety of predefined tiles with a termination shunt and different approach lengths may be available for selection by the user.

A triangle symbol represents a unidirectional track circuit and corresponds to a track module 208 (see GCP system 200 of FIG. 2) for monitoring each track 402, 404. The direction of the unidirectional track circuit is shown by the orientation of the triangle, wherein the apex of the triangle points in the direction of the approaching train.

Symbols 420a, 420b represent a first track circuit, GCP1, including transmitters T1, T2. Transmitter T1 of track circuit 420a transmits AC signal(s) having different frequencies, for example 86 Hz and 2.3 kHz. Transmitter T2 of GCP1 (420b) transmits an AC signal with a frequency of 156 Hz. An asterisk in the triangle symbol indicates that the island circuit is associated with the track circuit. In our example, track circuit GCP1 (420a) further handles the island circuit.

Symbols 420c, 420d, 420e belong to a second track circuit, GCP2, including multiple transmitters T1, T2, T3. Each transmitter T1, T2, T3 transmits an AC signal with a specific frequency. Transmitter T1 (420c) transmits an AC signal with 970 Hz, transmitter T2 (420d) transmits an AC signal with 114 Hz and transmitter T3 (420e) transmits an AC signal with 114 Hz.

Further, the track plan 400 may include description or other information 460 relevant to the specific crossing.

In another embodiment, the configuration editor 300 and the track plan 400 may include remote devices controlling the crossing, which may already be installed in the field and not being configured as part of this specific track plan 400 but can be added by the user to give a more complete visual picture of the context of the crossing being designed.

The designed track plan 400, using the graphical configuration editor 300, can be used as a basis for the user to configure necessary parameters for the crossing, for example as basis for configuring/programming GCP system 200 as shown in FIG. 2. Further, the track plan 400 can be shown to maintenance personnel in the field via graphical user interface(s) provided by the crossing equipment. For example, the track plan 400 can be shown in display 204 of GCP system 200, see FIG. 2. In other words, the display 204 of GCP system 200 shows the track layout/track plan 400 and uses internal data to ‘animate’ the track layout as to state(s) of crossing devices, trains present, etc. Further, the track plan 400 may be annotated, for example by maintenance personnel, with the state of the actual equipment, for example to show where trains are, or if an error is present in the system.

In another embodiment, such a track layout, e. g. track plan 400, can be used to improve tracking of trains through the crossing for diagnostic purposes. Currently there is insufficient information configured in most crossing systems to track a train from one predictor to another as the track layout has not been captured. The described solution of the graphical configuration editor 300 can provide the necessary information.

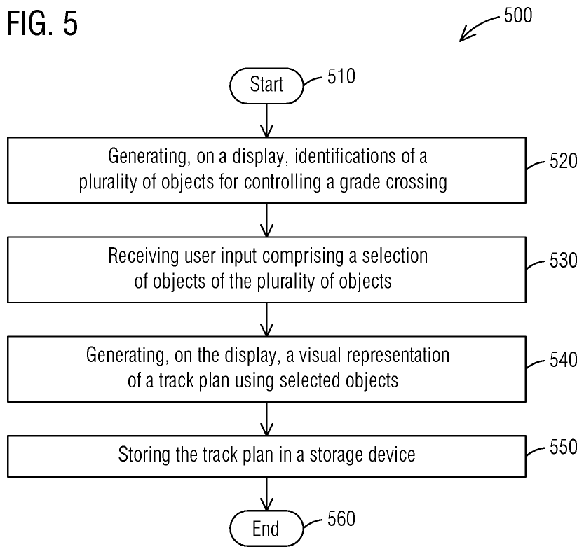

FIG. 5 illustrates a flow chart of a method 500 for creating a graphical representation of a track plan in accordance with embodiments of the present disclosure. In an example, the method 500 may be performed utilizing a graphical configuration editor 300 as described with reference to FIG. 3.

While the method 500 is described as a series of acts or steps that are performed in a sequence, it is to be understood that the method 500 may not be limited by the order of the sequence. For instance, unless stated otherwise, some acts may occur in a different order than what is described herein. In addition, in some cases, an act may occur concurrently with another act. Furthermore, in some instances, not all acts may be required to implement a methodology described herein.

The method 500 may start at 510 and comprises an act 520 of generating, on a display 350, identifications of a plurality of objects 330 for controlling a grade crossing, an act 530 of receiving user input comprising a selection of objects out of the plurality of objects 330, an act 540 of generating, on the display 350, a visual representation of a track plan 400 using the selected objects 330, and an act 550 of storing the track plan 400 in a storage device. At 560, the method 500 may end.

As described with reference to FIG. 3 and FIG. 4, the identifications of the plurality of objects 330 comprise visual representations. At least some of the objects 330 include default programming parameters for a grade crossing controller, such as for example GCP system 200 of FIG. 2.

In another embodiment, the method 500 comprises programming a grade crossing controller based on the visual representation of the track plan 400, utilizing the default programming parameters of the selected objects 300. This means that the default programming parameter behind the objects 330 used in the track plan 400 are used for configuring or programming the grade crossing controller.

In another embodiment, the method 500 comprises storing the visual representation of the track plan 400 in the grade crossing controller for displaying on a display of the grade crossing controller, for example display 204 of GCP system 200.

In another embodiment, the method 500 comprises transmitting the visual representation of the track plan 400 to a remote database or a separate storage device. The remote database or separate storage device can be for example a remote operations control center or other type of remote storage location. The track plan 400 is then retrievable from the remote database via another device or application. For example, the track plan may be retrievable from the remote or external storage device via a web application or a mobile application.

In another exemplary embodiment of the present disclosure, a non-transitory computer readable medium storing executable instructions is provided, wherein the executable instructions, when executed by a computer perform a method for creating a representation of a track plan or track circuit as described herein, specifically as described in method 500 with reference to FIG. 5 and device 300 with reference to FIG. 3.

The graphical configuration editor 300 allows the designer/user to capture a highway crossing configuration in a manner that is instantly relatable to their standard track plans. Thus, it is more intuitive to a user, and he/she is less likely to make errors in the crossing design. Further, the graphical configuration editor 300 allows field personnel to easily relate the crossing equipment to the actual track layout, and thus makes troubleshooting easier. Furthermore, the editor 300 and created track plan 400 allow for better tracking of trains through the crossing which will allow diagnosis of issues related to the train rather than a specific track to be identified more easily.

It should be appreciated that acts associated with the above-described methodologies, features, and functions (other than any described manual acts) may be carried out by one or more data processing systems, via operation of at least one processor. As used herein, a processor corresponds to any electronic device that is configured via hardware circuits, software, and/or firmware to process data. For example, processors described herein may correspond to one or more (or a combination) of microprocessor, CPU, or any other integrated circuit (IC) or other type of circuit that is capable of processing data in a data processing system. The at least one processor that is described or claimed as being configured to carry out a particular described/claimed process or function may correspond to a CPU that executes computer/processor executable instructions stored in a memory in form of software and/or firmware to carry out such a described/claimed process or function. However, it should also be appreciated that such a processor may correspond to an IC that is hard wired with processing circuitry (e.g., an FPGA or ASIC IC) to carry out such a described/claimed process or function.

1. A graphical configuration editor for highway-rail grade crossings, the graphical configuration editor comprising:
a storage device comprising an application, and
a processor configured to execute instructions of the application to
generate, on a display, identifications of a plurality of objects for controlling a grade crossing,
receive user input comprising a selection of objects out of the plurality of objects,
generate, on the display, a visual representation of a track plan using the selected objects, and
store the track plan in the storage device.

2. The graphical configuration editor of claim 1,
wherein each object includes default programming parameters for a grade crossing controller.

3. The graphical configuration editor of claim 1,
wherein the identifications of the plurality of objects comprise visual representations.

4. The graphical configuration editor of claim 1, further comprising:
wherein the identifications of the plurality of objects comprise predefined tiles with visual representations.

5. The graphical configuration editor of claim 4,
wherein the predefined tiles are manually configurable.

6. The graphical configuration editor of claim 1,
wherein the plurality of objects comprises grade crossing device(s) of the grade crossing and/or remote devices for controlling the grade crossing.

7. The graphical configuration editor of claim 6,
wherein the plurality of objects comprises track lines, track circuits, termination shunts, insulated joints.

8. The graphical configuration editor of claim 6,
wherein the remote devices relate to devices installed in an environment of the grade crossing, wherein the remote devices are pre-configured and selectable to supplement the graphical representation of the track plan.

9. The graphical configuration editor of claim 1,
wherein the selected objects and/or the visual representation of the track plan are manually configurable.

10. A grade crossing controller comprising a storage device and a display, wherein the grade crossing controller stores a graphical representation of a track plan and is configured to display the graphical representation of the track plan on demand.

11. A method for creating a visual representation of a track plan, the method comprising:
generating, on a display, identifications of a plurality of objects for controlling a grade crossing,
receiving user input comprising a selection of objects out of the plurality of objects,
generating, on the display, a visual representation of a track plan using the selected objects, and
storing the track plan in a storage device.

12. The method of claim 11,
wherein the identifications of the plurality of objects comprise visual representations.

13. The method of claim 11,
wherein each object includes default programming parameters for a grade crossing controller.

14. The method of claim 13, further comprising:
programming a grade crossing controller based on the visual representation of the track plan, utilizing the default programming parameters of the selected objects.

15. The method of claim 14, further comprising:
storing the visual representation of the track plan in the grade crossing controller.

16. The method of claim 15, further comprising:
displaying the visual representation of the track plan on a display of the grade crossing controller.

17. The method of claim 11, further comprising:
transmitting the visual representation of the track plan to a remote storage device,
wherein the track plan is retrievable from the remote storage device via another device or application.

18. The method of claim 17,
wherein the remote storage device is located at a remote operations control center.

19. The method of claim 17,
wherein the track plan is retrievable from the remote storage device via a web application or a mobile application.

20. A non-transitory computer readable medium storing executable instructions that when executed by a computer perform a method for creating a visual representation of a track plan as claimed in claim 11.
